(19) United States
(12) Patent Application Publication
(10) Pub. No.: US 2025/0191975 A1
(43) Pub. Date: Jun. 12, 2025

(54) ETCHED DIE SINGULATION SYSTEMS AND RELATED METHODS

(71) Applicant: SEMICONDUCTOR COMPONENTS INDUSTRIES, LLC, Scottsdale, AZ (US)

(72) Inventors: Bingzhi SU, Boise, ID (US); Yong LIU, Cumberland Foreside, ME (US)

(73) Assignee: SEMICONDUCTOR COMPONENTS INDUSTRIES, LLC, Scottsdale, AZ (US)

(21) Appl. No.: 18/534,804

(22) Filed: Dec. 11, 2023

(51) Int. Cl. H01L 21/78; H01L 21/308; H01L 27/146

(52) U.S. Cl. CPC H01L 21/78; H01L 21/308; H10F 39/018

(57) ABSTRACT

Implementations of a method of singulating a plurality of die from a substrate may include removing a die stack coupled to a substrate in a die street by etching the die stack to expose a top surface of a substrate material of the substrate in the die street. The first width of the top surface of the substrate material may be exposed. The method also may include forming a plurality of die by singulating, using a kerf width of a second width, the exposed substrate material of the substrate in the die street. The second width may be smaller than the first width.

### BACKGROUND

### 1. Technical Field

Aspects of this document relate generally to plasma die singulation systems and methods. More specific implementations involve methods of etching and singulating semiconductor die from a substrate.

### 2. Background

Semiconductor devices include integrated circuits found in common electrical and electronic devices, such as phones, desktops, tablets, other computing devices, and other electronic devices. Semiconductor packages have been devised that work to protect semiconductor devices from shock, vibration, humidity, and electrostatic discharge.

### SUMMARY

Implementations of a method of singulating a plurality of die from a substrate may include removing a die stack coupled to a substrate in a die street by etching the die stack to expose a top surface of a substrate material of the substrate in the die street. The first width of the top surface of the substrate material may be exposed. The method also may include forming a plurality of die by singulating, using a kerf width of a second width, the exposed substrate material of the substrate in the die street. The second width may be smaller than the first width.

Implementations of a method of singulating a plurality of die from a substrate may include one, all, or any of the following:

Removing the die stack may occur prior to forming the plurality of die.

The etching may include wet etching or dry etching.

Etching further may include: forming a patterned layer over the die stack, the patterned layer exposing the die stack; etching the die stack; and removing the patterned layer.

Forming the patterned layer may include using a photoresist.

Forming the patterned layer may include using one of screen printing or stencil printing.

The die stack may include two layers.

The die stack may include three layers.

The die stack may include a silicon layer and two metal/oxide layers.

The die stack may include a complementary metal oxide semiconductor (CMOS) image sensor bonded to an application specific integrated circuit (ASIC) device.

Removing the die stack further may include removing a silicon layer coupled over the die street.

Implementations of a method of singulating a plurality of die from a substrate may include removing at least one metal/oxide layer coupled to a substrate by etching the at least one metal/oxide layer to expose a remaining surface of a substrate material of the substrate and forming a plurality of die by singulating the remaining surface of the substrate material of the substrate in a die street. The portion of the remaining surface of the substrate material may remain exposed after singulating.

Implementations of a method of singulating a plurality of die from a substrate may include one, all, or any of the following:

The at least one metal/oxide layer may be removed prior to singulating the plurality of die.

The etching may include wet or dry etching.

Etching further may include: forming a patterned layer over the at least one metal/oxide layer, the patterned layer exposing the at least one metal/oxide layer; etching the at least one metal/oxide layer; and removing the patterned layer.

Forming the patterned layer may include using a photoresist.

Forming the patterned layer may include using one of screen printing or stencil printing.

The at least one metal/oxide layer may include two metal/oxide layers.

The at least one metal/oxide layer may include three layers.

Implementations of a method of singulating a plurality of die from a substrate may include entirely etching a thickness of a die stack to expose a top surface of a substrate material of a substrate and a sidewall of the die stack and forming a plurality of die by singulating the substrate material in a die street. The portion of the top surface of the substrate and the sidewall may remain after singulating.

Implementations of a method of singulating a plurality of die included in a substrate may include removing at least one layer coupled to a substrate by etching the at least one layer down to the substrate where a portion of the at least one layer remains coupled to the substrate. The method may also include forming a plurality of die included in the substrate by singulating the substrate material of the substrate in a die street where a portion of the substrate material remains adjacent the remaining portion of the at least one layer after singulating.

Implementations of a method of singulating a plurality of die included in a substrate may include etching a first area of a die stack to expose a substrate material of a substrate and forming a plurality of die included in the substrate by singulating the die stage in a die street. The first area may be larger than an area of the die street.

Implementations of a method of singulating a plurality of die included in a substrate may include etching a die stack in a die street to expose a top surface of a substrate material of a substrate and a sidewall of at least one layer coupled to the substrate. The method may also include forming a plurality of die included in the substrate by singulating the substrate material in a die street where a portion of the top surface of the substrate material and the sidewall of the at least one layer remain after singulating.

Implementations of a method of singulating a plurality of die included in a substrate may include etching at least one layer coupled to a substrate to provide an exposed surface of the substrate and singulating a plurality of die included in the substrate by sawing the exposed surface of the substrate in a die street. A width of the exposed surface of the substrate may be wider than a cut width of a saw blade used in the sawing.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional side view of an implementation of a substrate with a plurality of layers coupled thereto;

FIG. 2 is a cross sectional side view of the substrate of FIG. 1 with the plurality of layers in a die street region removed;

FIG. 3 is a cross sectional side view of the substrate of FIG. 1 singulated into semiconductor die;

FIG. 4 is a cross sectional side view of an implementation of a singulated semiconductor die;

FIG. 5 is a top view of an implementation of a singulated semiconductor die;

FIGS. 6 and 7 are cross sectional side views of a substrate coupled to a plurality of layers;

FIG. 8 is the cross sectional side view of the substrate of FIG. 6 being subject to electromagnetic radiation exposure;

FIG. 9 is a cross sectional side view of the substrate of FIG. 8 following a baking process;

FIG. 10 is a cross sectional side view of the substrate of FIG. 9 after a development process that exposes the die street;

FIG. 11 is a cross sectional side view of the substrate of FIG. 10 after etching in the die street and photoresist removal;

FIG. 12 is a cross sectional side view of the substrate of FIG. 11 after singulating;

FIG. 13 is a partial view of the substrate of FIG. 12;

FIG. 14 is a cross sectional side view of an implementation of an etched and singulated semiconductor die;

FIG. 15 is a partial view of the etched and singulated semiconductor die of FIG. 14;

FIG. 16 is a top view of an implementation of a substrate having one or more layers coupled over the substrate;

FIG. 17 is the top view of the substrate of FIG. 16 with the material of the one or more layers in a die street region removed; and

FIG. 18 is a top view of the substrate of FIG. 16 following singulation into semiconductor die.

### DESCRIPTION

This disclosure, its aspects and implementations, are not limited to the specific components, assembly procedures or method elements disclosed herein. Many additional components, assembly procedures and/or method elements known in the art consistent with the intended systems and methods of die singulation will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such systems and methods of die singulation, and implementing components and methods, consistent with the intended operation and methods.

Referring to FIG. 1, a cross sectional side view of a substrate 2 coupled to a plurality of layers 4 is illustrated. The term “substrate” refers to a semiconductor substrate as a semiconductor substrate is a common type of substrate, however, “substrate” is not an exclusive term that is used to refer to all semiconductor substrate types. Similarly, the term “substrate,” may refer to a wafer as a wafer is a common type of substrate, however, “substrate” is not an exclusive term that is used to refer to all wafers. The various semiconductor substrate types disclosed in this document that may be utilized in various implementations may be, by non-limiting example, round, rounded, square, rectangular, or any other closed shape. In various implementations, the substrate 2 may include a substrate material such as, by non-limiting example, single crystal silicon, silicon dioxide, glass, gallium arsenide, sapphire, ruby, silicon on insulator, silicon carbide, polycrystalline or amorphous forms of any of the foregoing, and any other substrate material useful for constructing semiconductor devices. In particular implementations, the substrate may be a silicon-on-insulator substrate. In various implementations, the substrate 2 is thinned. In particular implementations, the substrate 2 may be less than 30 micrometers (um) thick, less than 50 μm thick, and/or less than 100 μm thick. In other implementations, the substrate may be more than 100 μm thick and/or may not be thinned.

Referring again to FIG. 1, in various implementations an application specific integrated circuit (hereinafter ASIC) 6 device is illustrated coupled to a complementary metal oxide semiconductor (hereinafter CMOS) image sensor 8. The ASIC device 6 includes substrate 2 and a first metal layer 10 disposed thereon. The CMOS sensor 8 includes a second metal/oxide layer 12 coupled to the first metal/oxide layer 10 and a silicon layer 14 coupled to the second metal/oxide layer 12. Metal/oxide layers 10, 12 and silicon layer 14 are referred to collectively herein as layers 4.

In various implementations, a top side 3 of the substrate 2 may be coupled to metal/oxide layers 10, 12. This is true where the ultimate semiconductor device is a backside illuminated (BSI) image sensor device. The metal/oxide layers 10, 12 may include, by non-limiting example, metal oxides, copper, aluminum, nickel, any other metal, any alloy thereof, oxides thereof, or any combination thereof. In various implementations, the substrate 2 may be directly coupled to the first metal/oxide layer 10. In other implementations (though not illustrated), other layers, such as a metal seed layer, may be coupled between the metal/oxide layer 10 and the substrate 2.

Still referring to FIG. 1, a silicon layer 14 of the CMOS sensor 8 is one of the plurality of layers 4. In various implementations the silicon layer 14 may include, by non-limiting example, silicon, silicon nitride, oxides, metal electrical test structures, electrical test pads, silicon dioxide, polyimides, metal pads, residual underbump metallization (UBM), any combination thereof, or any other layer or material capable of facilitating electrical or thermal connection between the one or more semiconductor die and/or protecting the one or more semiconductor die from contaminants. Because of this, the term “silicon material” and “silicon layer,” as used herein, includes any of the aforementioned materials whether the material was deposited to act as a passivating material or whether the material merely forms a non-plasma etchable portion or layer in the die street region.

The silicon layer 14 may be coupled over the metal/oxide layers 10, 12 as illustrated in FIG. 1. The silicon layer 14 may include, by non-limiting example, silicon, silicon dioxide, silicon nitride, polyimide, a polymer material, or any other semiconductor substrate or passivation layer material type. In various implementations, multiple layers of passivating materials may be included in the plurality of layers 4. While the implementation illustrated in FIG. 1 includes three layers in the form of the metal/oxide layers 10, 12 and the silicon layer 14 coupled over the substrate 2, other implementations may include additional metal layers, additional passivation layers, additional other layers, layers without the metal/oxide layers 10, 12, layers without the silicon layer 14, or any combination thereof. The layers may fully cover the substrate 2, cover a majority of the substrate, or may only partially cover the substrate.

While the methods disclosed herein are focused on singulating the substrate 2, it is understood that the substrate 2 may include and/or be coupled to other elements not illustrated, such as a plurality of semiconductor devices. In such implementations, the plurality of semiconductor devices may include a power semiconductor device or non-power semiconductor device. In implementations where a plurality of power devices are coupled to the substrate, the power devices may include, by non-limiting example, a metal oxide field effect transistor (MOSFET), an insulated gate bipolar transistor (IGBT), a diode, a thyristor, a silicon controlled rectifier (SCR), or any other kind of power semiconductor device.

The substrate 2 and the plurality of layers 4 include a die street 16 having a die street width W16 therethrough and a kerf region18 having kerf width W18 therethrough. The first width W16 of die street 16 is wider than the second width W18 of the kerf width. The kerf width W18 is the width of the saw blade or cut line (where sawing is not used) used for singulating the die. As illustrated by FIG. 1, the metal/oxide layers 10, 12 and the silicon layer 14 extend through the regions of the die street 16 and kerf region 18. In various implementations, electrical testing devices and corresponding probe pads providing access to the electrical testing devices and structures may be included in at least one of the plurality of layers 4 and in the region of the die street 16.

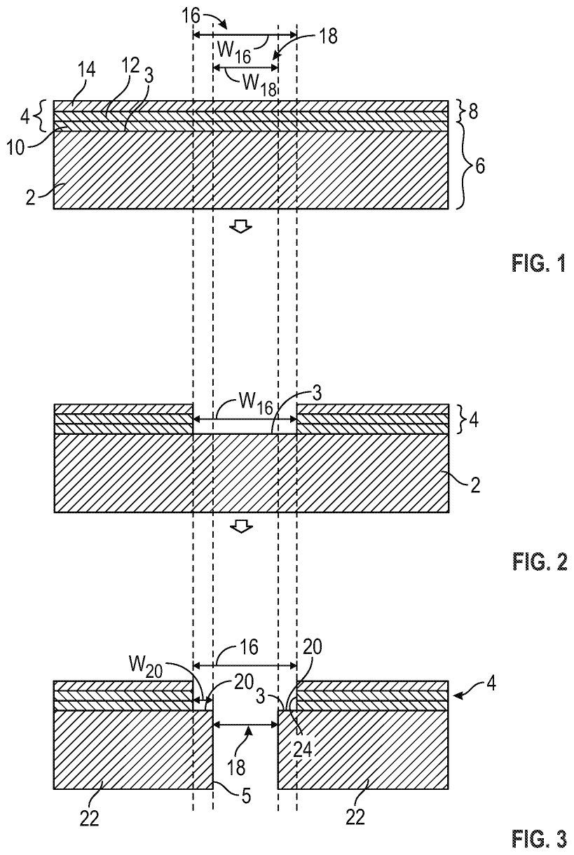

Referring to FIG. 2, the cross sectional side view of the substrate of FIG. 1 with the plurality of layers 4 in the die street 16 removed is illustrated. As used herein, when “removal” of a layer in a die street is discussed, it is understood that this also includes removal of the portion of the layer in the die street and does not require removal of the entire layer. In various implementations, a method of singulating a plurality of die included in a substrate includes exposing a substrate material of the substrate 2 in the die street 16 through removing the plurality of layers 4 in the die street 16 coupled to the substrate 2. In various implementations a full width W16, less than a full width W16, or a width greater than the kerf width W18, may be etched to expose the top surface 3 of the substrate material of substrate 2. In implementations having only a metal/oxide layer rather than a plurality of layers or a metal/oxide layer in addition to the plurality of layers, or metal included in the plurality of layers, the method may include removing the metal or metal layer in the die street 16. Similarly, in implementations having only a silicon layer (or some other layer) rather than the plurality of layers, the method includes removing the silicon layer (or some other layer) in the die street 16.

Delamination is the separation between two coupled interfaces within a package and may occur between, for example, any of the layers 4 and substrate 2 or the CMOS image sensor 8 and the ASIC device 6 after they have been bonded together. Delamination of layers can lead to reliability issues for the die. Delamination may occur when defects are present in the layers, particularly the metal/oxide layers. The dicing or singulating process is often responsible for creating the initial defects in the layers 4 that lead to delamination during packaging or during operation of the semiconductor device. The sidewalls of the kerf, or the sidewalls of the die street following a singulation operation, may include singulation damage. Using a saw, laser, water jet, or scribe to remove a portion of the substrate results in the creation of chips and cracks in the sidewalls of the die street and layers adjacent to the die street. The presence of the cracks and chips has the potential to compromise the reliability of the resulting semiconductor package (and reduce the die strength) if/when the cracks and chips propagate into the device portion of the semiconductor die during operation. Since the saw (or other) mechanical singulation process involves the rubbing of the rotating blade or pressing of another object like a stylus against the die surface, the chipping and cracking can only be managed through changing saw (or other) processing variables (substrate feed speed, blade kerf width, cut depth, multiple saw cuts, blade materials, etc.) but cannot entirely be eliminated.

Singulating via mechanical dicing may also generate defects in the metal and/or oxide layers 10, 12 which can lead to delamination. Singulating via laser grooving may have some advantages over mechanical dicing, though laser grooving still results in small defects due to the heat-induced stress created during the dicing process. Even these small defects may contribute to delamination when the die is encapsulated, for example, in image ball grid array (hereinafter iBGA) packages. It has been observed that defects larger than 1 micrometer may propagate resulting in delamination whereas defects smaller than 0.2 micrometer are not likely to result in delamination.

To reduce die stack delamination in iBGA image sensor packages, an exposure feature is introduced to the die stack. The plurality of layers 4 coupled to the substrate 2 are removed from the die street 16, in other words, silicon layer 14 and second metal/oxide layer 12 of the CMOS sensor 8 and the first metal/oxide layer 10 of ASIC device 6 are removed from die street 16 (die street region). This removal may take place across the entire width of the die street or across only a portion of the width of the die street in various method and system implementations. The layers 4 may be removed by an etching process, for example, wet etching or dry etching. The etching process reduces defects in the metal and/or oxide layers 10, 12 in order to reduce or minimize delamination in the die or subsequently formed package. The die street width W16 is thus intentionally wider than the kerf width W18, so that the etched die street width W16 is wider than the width of the dicing blade. By etching a wider area than needed for dicing or another singulating process, contact with the metal and/or oxide layers 10, 12 can be reduced or even eliminated during the dicing process which reduces or prevents the creation of defects in the metal and/or oxide layers 10, 12, thereby reducing or potentially eliminating the risk of delamination.

Referring to FIG. 3, a cross sectional side view of the substrate of FIG. 1 singulated into semiconductor die is illustrated. Exposed features/surfaces 20 on the top surfaces 3 of substrates 2 remain after dicing. The width of the exposed feature 20, width W20, is the difference between the etched die street width W16 and the kerf width W18 removed during the singulating process. The exposed feature width W20 provides sufficient space between the dicing blade or mechanism and sidewalls 24 of the layers 4 to reduce or eliminate contact with the sidewalls 24 during the singulating process, thus, reducing or preventing the creation of defects in the metal and/or oxide layers 10, 12. This has the effect of reducing or potentially eliminating the risk of delamination. In some implementations, the exposed feature 20 may be partially etched where an overetch is used to etch the material of the die stack that includes the metal and/or oxide layers.

In various implementations, the kerf width W18, the die street width W16, or the removed portion of the metal and/or oxide layers 10, 12 and/or silicon layer 14 in the die street 16, may vary based upon the specific method used and the particular dimensions of each feature.

In various implementations, a method of singulating a plurality of die included in a substrate includes singulating a plurality of die 22 included in the substrate 2 through etching the layers 4 in the die street 16 then proceeding with a singulating dicing process. In various implementations, a plasma etch process marketed under the tradename BOSCH® by Robert Bosch GmbH, Stuttgart, Germany (the “Bosch process”), may be used to singulate the substrate material. In other implementations, a saw, laser, water jet, or scribe and break processes may be used to singulate the plurality of die 22 from the substrate 2.

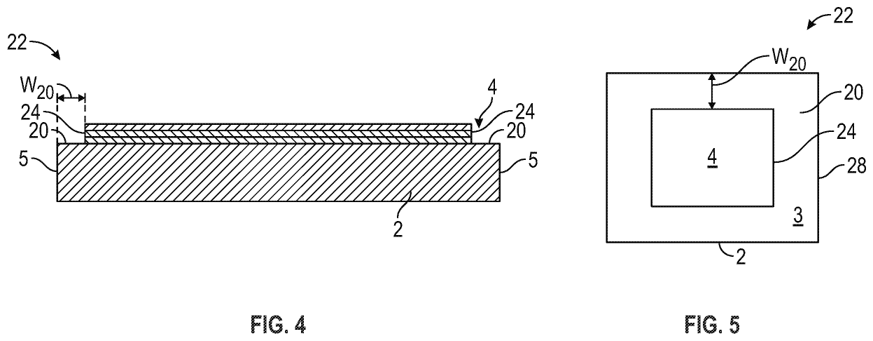

Referring to FIG. 4, a cross sectional side view of a semiconductor die 22 is illustrated. Die 22 includes substrate 2 with exposed feature/surface 20 disposed on the top surface 3 of the substrate 2. As shown, the exposed feature 20 has a width W20 that is the distance between a sidewall 5 of substrate 2 and a sidewall 24 of the layers 4. In various implementations, the exposed feature 20 may be present on the top surface 3 around the perimeter of the substrate 2 such that the sidewalls 24 of the layers 4 are a width W20 away from the sidewalls 5 of the substrate 2. In various implementations, the exposed feature 20 may be located in designated regions or partially around the perimeter of the substrate 2.

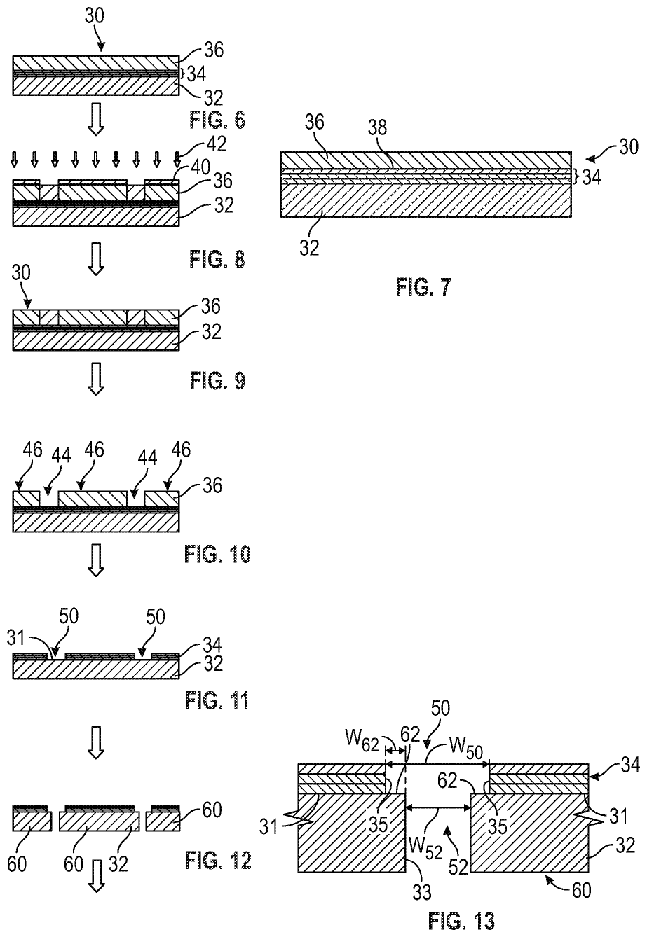

FIG. 5 illustrates a top view of a singulated semiconductor die 22 including the exposed feature/surface 20. The exposed feature/surface 20 is disposed on the top surface 3 of substrate 2. As shown, the exposed feature/surface 20 has a width W20 that is the distance between a perimeter 28 of substrate 2 and the layers 4. In various implementations, the exposed feature/surface 20 may be present on the top surface 3 around the perimeter 28 of the substrate 2 such that the sidewalls 24 of the layers 4 are a width W20 away from the perimeter 28 of the substrate 2. In various implementations, the exposed feature/surface 20 may be located in designated regions or partially around the perimeter 28 of the substrate 2. In various implementations, the width W20 of the exposed surface/feature 20 is generally uniform around perimeter 28 but may vary as desired or due to manufacturing processes. Referring to FIGS. 6-15, a method of singulating a plurality of die from a substrate similar to FIGS. 1-5 is illustrated. Referring to FIGS. 6 and 7, a cross sectional side view of a substrate 32 coupled to one or more layers 34 is illustrated. The substrate 32 may be the same as or similar to any substrate type disclosed herein and the one or more layers 34 may include any type of layer disclosed herein. Additionally, a photoresist layer 36 has been applied to a top surface 38 of the die stack 30. As shown in FIG. 7, three layers 34 are coupled to substrate 32 and the layer 36 of photoresist material is disposed on the top surface 38 of layers 34. Referring to FIG. 8, the cross sectional side view of the substrate of FIG. 6 during imaging of the photoresist layer 36 using electromagnetic radiation is illustrated. The image/reticle pattern 40 shown above the photoresist layer 36 includes a pattern of the die street regions (if a positive photoresist material is used) or a pattern of the die regions (if a negative photoresist material is used). During imaging, the photoresist layer 36 is exposed to electromagnetic radiation 42, for example, UV light, to cause chemical reactions in the exposed regions of the photoresist that will ultimately create the desired pattern into the photoresist layer 36. The die stack 30 then undergoes post exposure baking process illustrated in FIG. 9 before the exposed photoresist material is removed (in the case of a positive photoresist) or the unexposed photoresist material is removed (in the case of a negative photoresist) using a development process as illustrated in FIG. 10.

The baking process occurs after exposure to light or other electromagnetic radiation 42. During the baking process, the die stack 30 with the exposed photoresist material 36 thereon is heated. Post exposure baking may reduce the presence of standing waves present in the photoresist material 36 after exposure. Post exposure baking may also be advantageous when negative photoresist techniques are used to assist with helping the exposed photoresist remain and provide sharp features following the development process.

Referring now to FIG. 10, the substrate is illustrated after the developing processing for the photoresist layer 36 has occurred that now forms the pattern of the die streets/die street regions that will be later etched into die stack 30. The development process involves treating the photoresist layer 36 with chemicals that promote chemical reactions where the exposed (or unexposed) parts of the photoresist layer 36 are dissolved and carried away in a rinse process leaving the desired mask or pattern in place. The developed pattern in the photoresist layer 36 serves as a physical mask that protects areas on the die stack 30 from chemical attack during subsequent etching. As illustrated in FIG. 10, the exposed areas 44 of photoresist layer 36 are removed following the developing process.

FIG. 11 illustrates die stack 30 after the die stack 30 was etched using any etching method disclosed herein and the photoresist layer 36 has been removed using, by non-limiting example, ashing, solvent stripping, or any combination thereof. As a result of the etching, a top surface 31 of substrate 32 is exposed in the die streets 50/die street regions. Die streets 50 now correspond with the exposed areas 44 of photoresist 36 illustrated in FIG. 10.

Referring to FIGS. 12 to 15, cross sectional side views of the substrate of FIG. 11 following singulation into semiconductor die are illustrated. The method for singulating a plurality of die 60 included in the substrate 32 may include singulating the plurality of die 60 using any method disclosed herein. As illustrated by FIGS. 12 and 13, the die street width W₅₀ is intentionally wider than the kerf width W₅₂, so the etched area/exposed area of the substrate is wider than the width of the dicing blade or other singulation process (laser/plasma etch/water jet/scribe and break). As a result of the etching process, an exposed feature/surface 62 of substrate 32 is created between sidewalls 35 of layers 34 and an edge or sidewall 33 of substrate 32. The top surface 31 of substrate 32 is exposed in exposed feature 62. By etching a wider area than needed for dicing or singulating, contact with the layers 34 can be reduced or even eliminated during the dicing process where a blade is used which reduces or prevents the creation of defects in the layers 34, thereby reducing or eliminating the risk of delamination in the die 60.

Referring now to FIG. 13, exposed features 62 on the top surfaces 31 of substrates 32 remain after the dicing process. The width of the exposed feature 62, width W₆₂, is the difference between the etched die street width W₅₀ and the kerf width W₅₂ removed during the singulating process as illustrated in FIG. 13. The exposed feature width W₆₂ provides sufficient space between the dicing blade or mechanism and sidewalls 35 of the layers 34 to reduce or eliminate contact with the sidewalls 35 during the singulating process, thus, reducing or preventing the creation of defects in the layers 34 which reduces or eliminates the risk of delamination, particularly where a saw blade is employed. In some implementations, the exposed feature 62 may also be etched where an overetch process is used to etch the die stack layers. In various implementations the kerf width W₅₂, the die street width W₅₀, or the removed portion of layers 34 in die street 50, may vary based upon the specific method used and the dimensions of the die street, etc.

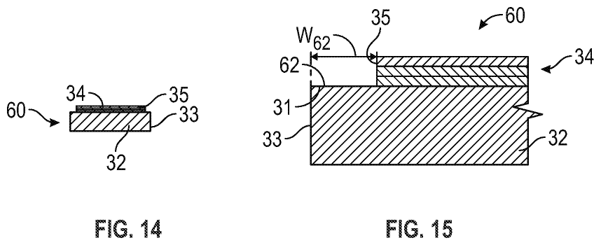

Referring to FIGS. 14 and 15, a cross sectional side view of an implementation of a semiconductor die 60 is illustrated. Die 60 includes substrate 32 with exposed feature/surface 62 disposed on the top surface 31 of the substrate 32. As illustrated in FIG. 15, the exposed feature 62 has a width W₆₂ that is the distance between a sidewall 33 of substrate 32 and a sidewall 35 of the layers 34. In various implementations, the exposed feature 62 may be present on the top surface 31 adjacent a perimeter of the substrate 32 such that the sidewalls 35 of the layers 34 are a distance W₆₂ away from the sidewalls 33 or perimeter of the substrate 32. In various implementations, the exposed feature 62 may be located in designated regions or fully or partially around the perimeter of the substrate 32.

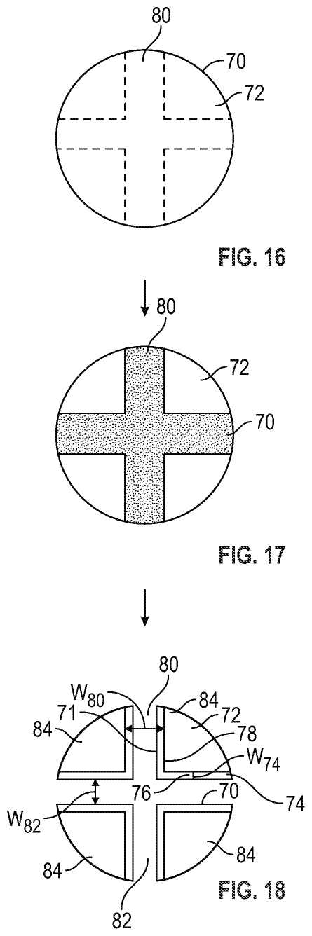

Referring to FIGS. 16 to 18, a top view of a semiconductor substrate at various points during an implementation of a method of singulating a plurality of die from a substrate similar to or the same as the methods illustrated in FIGS. 1-15 is illustrated. Referring specifically to FIG. 16, a top view of a portion of a substrate having one or more layers 72 coupled over the substrate 70 is illustrated. The portion of the substrate 70 illustrated includes intersecting die streets 80 (a die street intersection). The substrate 70 may be any type of substrate disclosed herein and the one or more layers 72 may include any type of layer disclosed herein. Referring to FIG. 17, a top view of the substrate of FIG. 16 with the material of the one or more layers 72 in the die street 80 removed is illustrated. In the various method implementations, the one or more layers 72 are removed using etching using any etching method (including any patterning method for the etching) disclosed herein. FIG. 17 illustrates how the exposed substrate material of the substrate 70 in the die street 80/die street regions occurs through the removal of the one or more layers 72 in the die street 80 coupled to the substrate 70.

Referring to FIG. 18, a top view of the substrate 70 of FIG. 16 following singulation of the substrate material into semiconductor die 84 is illustrated. As illustrated by FIG. 18, the method includes singulating a plurality of die 84 from the substrate 70 using any method disclosed herein. As shown in FIG. 18, the kerf 82 is narrower than the die street 80. Thus, the kerf width W₈₂ is narrower than the die street width W₈₀. Consequently, a top surface 76 of substrate 70 is exposed by the previous etching process forming an area that is wider/larger than the kerf width W₈₂. The resulting die 84 includes substrate 70 with exposed feature 74 disposed on the top surface 76 of the substrate 70. The exposed feature 74 has a width W₇₄ that is the distance between a kerf width W₈₂ and the die street width W₈₀. In various implementations, the exposed feature 74 is present on the top surface 76 adjacent a perimeter of the substrate 70 such that the sidewalls 78 of the layers 72 are a distance W₇₄ away from the sidewalls 71 of the substrate 70. In various implementations, the exposed feature 74 may be located in designated regions, fully, or partially around the perimeter of the substrate 70. As shown in the implementation illustrated in FIG. 18, the exposed feature 74 is clearly visible on the top surface 76 of each die 84 after singulation.

The plurality of die singulated from the substrates disclosed herein may include any type of semiconductor die including any type disclosed herein. The exposed feature/surface is created before dicing or singulating process occurs, while the die are still in the substrate or wafer. By etching layers in the die stack at a width greater than needed for singulating, the reliability of the die may be improved as less damage is induced into the layers as compared to singulating the plurality of die through sawing, lasering, or other singulation methods. Further, the die may be strengthened as the etch may provide a flawless or substantially flawless surface finish and/or the exposed feature may reduce or eliminate defects that could lead to delamination in the die stack. Moreover, the photolithography techniques used to create the exposed feature provide precise and controlled implementation of the feature. The improved reliability and strength of the die may be especially important when the die are utilized in power semiconductor devices. Power semiconductor devices, such as an IGBT, may be coupled to a large lead frame and may include a large heat sink. The larger components of the semiconductor package may result in additional strain to the semiconductor die which may result in failure of the die (and especially of thinned die) if not sufficiently defect free.

The exposed feature on the die stack may reduce or eliminate initial defects that can lead to delamination. This improvement can enhance the overall reliability of iBGA packages, ensuring their performance and longevity. Thus, the exposed feature on the substrate may be adopted widely due to the increasing popularity of iBGA packages in automation applications. The improved reliability of iBGA packages through the implementation of the exposed feature on the die stack may also instill confidence in customers.

The methods of singulating a plurality of die disclosed herein may be utilized with thinned (or non-thinned) substrates having one or more layers coupled thereto in a variety of designs.

In places where the description above refers to particular implementations of systems and methods for die singulation and related methods and implementing components, sub-components, methods and sub-methods, it should be readily apparent that a number of modifications may be made without departing from the spirit thereof and that these implementations, implementing components, sub-components, methods and sub-methods may be applied to other systems and method for die singulation and related methods.

What is claimed is:

1. A method of singulating a plurality of die from a substrate, the method comprising:
removing a die stack coupled to a substrate in a die street by etching the die stack to expose a top surface of a substrate material of the substrate in the die street, wherein a first width of the top surface of the substrate material is exposed; and
forming a plurality of die by singulating, using a kerf width of a second width, the exposed substrate material of the substrate in the die street, wherein the second width is smaller than the first width.

2. The method of claim 1, wherein removing the die stack occurs prior to forming the plurality of die.

3. The method of claim 1, wherein the etching comprises wet etching or dry etching.

4. The method of claim 1, wherein etching further comprises:
forming a patterned layer over the die stack, the patterned layer exposing the die stack;
etching the die stack; and
removing the patterned layer.

5. The method of claim 4, wherein forming the patterned layer comprises using a photoresist.

6. The method of claim 4, wherein forming the patterned layer comprises using one of screen printing or stencil printing.

7. The method of claim 1, wherein the die stack includes two layers.

8. The method of claim 1, wherein the die stack includes three layers.

9. The method of claim 1, wherein the die stack includes a silicon layer and two metal/oxide layers.

10. The method of claim 1, wherein the die stack includes a complementary metal oxide semiconductor (CMOS) image sensor bonded to an application specific integrated circuit (ASIC) device.

11. The method of claim 1, wherein removing the die stack further comprises removing a silicon layer coupled over the die street.

12. A method of singulating a plurality of die from a substrate, the method comprising:
removing at least one metal/oxide layer coupled to a substrate by etching the at least one metal/oxide layer to expose a remaining surface of a substrate material of the substrate; and
forming a plurality of die by singulating the remaining surface of the substrate material of the substrate in a die street, wherein a portion of the remaining surface of the substrate material remains exposed after singulating.

13. The method of claim 12, wherein the at least one metal/oxide layer is removed prior to singulating the plurality of die.

14. The method of claim 12, wherein the etching comprises wet or dry etching.

15. The method of claim 12, wherein etching further comprises:
forming a patterned layer over the at least one metal/oxide layer, the patterned layer exposing the at least one metal/oxide layer;
etching the at least one metal/oxide layer; and
removing the patterned layer.

16. The method of claim 15, wherein forming the patterned layer comprises using a photoresist.

17. The method of claim 15, wherein forming the patterned layer comprises using one of screen printing or stencil printing.

18. The method of claim 12, wherein the at least one metal/oxide layer includes two metal/oxide layers.

19. The method of claim 12, wherein the at least one metal/oxide layer includes three layers.

20. A method of singulating a plurality of die from a substrate, the method comprising:
entirely etching a thickness of a die stack to expose a top surface of a substrate material of a substrate and a sidewall of the die stack; and
forming a plurality of die by singulating the substrate material in a die street, wherein a portion of the top surface of the substrate and the sidewall remain after singulating.
